(19) United States
(12) Patent Application Publication
(10) Pub. No.: US 2024/0026563 A1
(43) Pub. Date: Jan. 25, 2024

(54) COMPOUND INTERNALLY-HEATED HIGH-PRESSURE APPARATUS FOR SOLVOTHERMAL CRYSTAL GROWTH

(71) Applicant: SLT Technologies, Inc., Los Angeles, CA (US)

(72) Inventors: Mark P. D'EVELYN, Vancouver, WA (US); Paul M. VON DOLLEN, Brush Prairie, WA (US)

(21) Appl. No.: 18/356,127

(22) Filed: Jul. 20, 2023

Related U.S. Application Data
(60) Provisional application No. 63/424,802, filed on Nov. 11, 2022.
(60) Provisional application No. 63/390,803, filed on Jul. 20, 2022.

(51) Int. Cl. C30B 7/10

(52) U.S. Cl. CPC C30B 7/10

(57) ABSTRACT

Embodiments of the disclosure include a crystal growth apparatus, comprising a cylindrical-shaped enclosure, a primary liner disposed within the cylindrical-shaped enclosure, wherein the primary liner comprises a cylindrical wall that extends between a first end and a second end, and an interior surface of the primary liner defines an interior region, at least one load-bearing annular insulating member disposed between the cylindrical-shaped enclosure and the primary liner, a plurality of heating elements disposed between the primary liner and the at least one load-bearing annular insulating member, at least one end closure member disposed proximate to a first end of the cylindrical-shaped enclosure, and a primary liner lid disposed proximate to the first end of the cylindrical wall of the primary liner. The at least one load-bearing annular insulating member comprising at least one of a packed-bed ceramic composition, the packed-bed ceramic composition having a density that is between about 30% and about 98% of a theoretical density of a 100%-dense ceramic having the same composition, or a perforated metal member, comprising a perforated metal foil or a plurality of perforated metal plates, wherein the perforations have a percent open area between about 25% and about 90%, and the perforations have a diameter between about 1 millimeter and about 25 millimeters.

### CROSS-REFERENCE TO RELATED APPLICATIONS

This application claims the benefit of U.S. provisional patent application Ser. No. 63/390,803, filed Jul. 20, 2022, and U.S. provisional patent application Ser. No. 63/424,802, filed Nov. 11, 2022, both of which are herein incorporated by reference.

### BACKGROUND

### Field

The present disclosure generally relates to processing of materials in supercritical fluids for growth of crystals useful for forming bulk substrates that can be used to form a variety of optoelectronic, integrated circuit, power device, laser, light emitting diode, photovoltaic, and other related devices.

### Description of Related Art

The present disclosure relates generally to techniques for processing materials in supercritical fluids, such as growth of single crystals. Examples of such crystals include metal nitrides, such as GaN, AlN, InN, InGaN, AlGaN, and AlInGaN. More specifically, embodiments of the disclosure include techniques for controlling parameters associated with material processing within a liner disposed within a high-pressure apparatus enclosure. Gallium nitride containing crystalline materials are useful as substrates for manufacture of optoelectronic and electronic devices, such as lasers, light emitting diodes, solar cells, photoelectrochemical water splitting and hydrogen generation devices, photodetectors, integrated circuits, and transistors, among other devices.

Supercritical fluids are used to process a wide variety of materials. A supercritical fluid is often defined as a substance beyond its critical point, i.e., critical temperature and critical pressure. A critical point represents the highest temperature and pressure at which the substance can exist as a vapor and liquid in equilibrium. In certain supercritical fluid applications, the materials being processed are placed inside a pressure vessel or other high-pressure apparatus. In some cases, it is desirable to first place the materials inside a container, liner, or capsule, which in turn is placed inside the high-pressure apparatus. In operation, the high-pressure apparatus provides structural support for the high pressures generated within the container or capsule holding the materials. The container, liner, or capsule provides a closed/sealed environment that is chemically inert and impermeable to solvents, solutes, and gases that may be involved in or generated by the process.

Supercritical fluids provide an especially ideal environment for growth of high-quality crystals, that is, a solvothermal process, in large volumes and low costs. In many cases, supercritical fluids possess the solvating capabilities of a liquid with the transport characteristics of a gas. Thus, on the one hand, supercritical fluids can dissolve significant quantities of a solute for recrystallization. On the other hand, the favorable transport characteristics include a high diffusion coefficient, so that solutes may be transported rapidly through the boundary layer between the bulk of the supercritical fluid and a growing crystal, and also a low viscosity, so that the boundary layer is very thin and small temperature gradients can cause facile self-convection and self-stirring of the reactor. This combination of characteristics enables, for example, the growth of hundreds or thousands of large α-quartz crystals in a single growth run in supercritical water. In some applications the fluid may remain subcritical, that is, the pressure or temperature may be less than the critical point. However, in all cases of interest here, the fluid is superheated, that is, the temperature is higher than the boiling point of the fluid at atmospheric pressure. The term “supercritical” will be used throughout to mean “superheated”, regardless of whether the pressure and temperature are greater than the critical point, which may not be known for a particular fluid composition with dissolved solutes.

Conventional pressure vessels for solvothermal crystal growth, or autoclaves, are externally heated. Consequently, to a first approximation, load-bearing elements of the pressure vessel experience essentially the same pressure and temperature as the crystal growth process. Commonly, the maximum pressure and temperature that can be achieved are limited by the creep characteristics of the material from which the pressure vessel body is fabricated, for example, a high-strength steel or a nickel-based superalloy. However, steel-based pressure vessels have insufficient properties for growth of materials such as the nitrides that require temperatures above 500 degrees Celsius, and nickel-based superalloys are very expensive and are difficult to scale to large dimensions.

Some of the limitations of externally-heated pressure vessels can be avoided by utilizing internal heating, so that load-bearing elements of the pressure vessel experience a similar pressure as the crystal growth process but are kept at much lower temperature, so that creep is less of an issue and, in many cases, high-strength steel alloys can be used as the load-bearing material. In some applications, an internal heater is separated from a high-strength enclosure by a load-bearing ceramic such as zirconia that acts as a thermal insulator, for example, as disclosed by D'Evelyn, et al. [U.S. Pat. No. 7,704,324] and by D'Evelyn [U.S. Pat. No. 8,097,081]. While this approach enables significantly-reduced costs compared to autoclaves fabricated from nickel-based superalloys, further cost reductions are desirable for large-scale manufacturing.

There is a large installed base of steel autoclaves, with inner diameters greater than 400 millimeters and lengths greater than 10 meters, for manufacturing of quartz crystals by hydrothermal crystal growth. However, the market need for quartz has diminished significantly over the last several decades, resulting in idle autoclave capacity. It would be highly desirable to be able to retrofit these autoclaves for large-scale ammonothermal crystal growth processes.

Therefore, what is needed is a compound internally-heated high-pressure apparatus that enables lower costs and greater scalability than superalloy-based autoclaves or internally-heated high-pressure apparatus that utilizes previously disclosed approaches.

### SUMMARY

According to the present disclosure, apparatus related to processing of materials for growth of crystals is provided. More particularly, the present disclosure provides an improved internally-heated high-pressure apparatus for crystal growth of a material in a supercritical fluid, including crystal growth of a group III metal nitride crystal by an ammonobasic or ammonoacidic technique, but there can be others. In other embodiments, the present disclosure provides methods suitable for synthesis of crystalline nitride materials, but it would be recognized that other crystals and materials can also be processed. Such crystals and materials include, but are not limited to, GaN, AlN, InN, InGaN, AlGaN, and AlInGaN, and others for manufacture of bulk or patterned substrates. Such bulk or patterned substrates can be used for a variety of applications including optoelectronic devices, lasers, light emitting diodes, solar cells, photoelectrochemical water splitting and hydrogen generation, photodetectors, integrated circuits, and transistors, among other devices.

The present disclosure achieves these benefits and others in the context of known process technology. However, a further understanding of the nature and advantages of the present disclosure may be realized by reference to the latter portions of the specification and attached drawings.

Embodiments of the disclosure include a crystal growth apparatus, comprising a cylindrical-shaped enclosure, a primary liner disposed within the cylindrical-shaped enclosure, wherein the primary liner comprises a cylindrical wall that extends between a first end and a second end, and an interior surface of the primary liner defines an interior region, at least one load-bearing annular insulating member disposed between the cylindrical-shaped enclosure and the primary liner, a plurality of heating elements disposed between the primary liner and the at least one load-bearing annular insulating member, at least one end closure member disposed proximate to a first end of the cylindrical-shaped enclosure, and a primary liner lid disposed proximate to the first end of the cylindrical wall of the primary liner. The at least one load-bearing annular insulating member comprising at least one of a packed-bed ceramic composition, the packed-bed ceramic composition having a density that is between about 30% and about 98% of a theoretical density of a 100%-dense ceramic having the same composition, or a perforated metal member, comprising a perforated metal foil or a plurality of perforated metal plates, wherein the perforations have a percent open area between about 25% and about 90%, and the perforations have a diameter between about 1 millimeter and about 25 millimeters.

Embodiments of the disclosure include a crystal growth apparatus, comprising: a cylindrical-shaped enclosure configured to provide radial support for processing a material in a fluid at a pressure above about 5 megapascal (MPa) and less than about 500 MPa and temperatures above about 200 degrees Celsius and less than about 900 degrees Celsius; a primary liner disposed within the cylindrical-shaped enclosure, wherein the primary liner comprises a cylindrical wall that extends between a first end and a second end, and an interior surface of the primary liner defines an interior region; at least one load-bearing annular insulating member disposed between the cylindrical-shaped enclosure and the primary liner; a plurality of heating elements disposed between the primary liner and the at least one load-bearing annular insulating member; at least one end closure member disposed proximate to a first end of the cylindrical-shaped enclosure, the at least one end closure member being configured to provide axial support for processing a material in a fluid within the interior region at a pressure above about 5 MPa and less than about 500 MPa and temperatures above about 200 degrees Celsius and less than about 900 degrees Celsius; and a primary liner lid disposed proximate to the first end of the cylindrical wall of the primary liner, the primary liner being configured to define an axial boundary of the interior region and to receive axial support from the at least one end closure member. The at least one load-bearing annular insulating member being characterized by a thermal conductivity between about 0.1 and about 10 watts per meter-Kelvin and comprising at least one of: a packed-bed ceramic composition, the packed-bed ceramic composition having a density that is between about 30% and about 98% of a theoretical density of a 100%-dense ceramic having the same composition; or a perforated metal member, comprising a perforated metal foil or a plurality of perforated metal plates having an individual thickness between about 0.05 millimeter and about 20 millimeters, wherein the perforations have a percent open area between about 25% and about 90%, and the perforations have a diameter between about 1 millimeter and about 25 millimeters.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope and may admit to other equally effective embodiments.

FIG. 1 is a schematic diagram showing an internally-heated high-pressure apparatus according to an embodiment of the present disclosure.

FIG. 2A is a schematic diagram showing a cross section of a load-bearing insulator component of an internally-heated high-pressure apparatus according to an embodiment of the present disclosure.

FIG. 2B is an expanded view of a schematic diagram showing a cross section of a load-bearing insulator component of an internally-heated high-pressure apparatus according to an embodiment of the present disclosure.

FIG. 3A is a schematic diagram of showing a cross section of a load-collar ring component of an internally-heated high-pressure apparatus according to an embodiment of the present disclosure.

FIG. 3B is an expanded view of a schematic diagram showing a cross section of a collar ring component of an internally-heated high-pressure apparatus according to an embodiment of the present disclosure.

FIG. 4A is a schematic diagram showing an expanded view of an upper portion of an internally-heated high-pressure apparatus according to an embodiment of the present disclosure.

FIG. 4B is a schematic diagram showing an expanded view of seal region of an internally-heated high-pressure apparatus according to an embodiment of the present disclosure.

FIG. 5A is a schematic diagram showing an alternative internally-heated high-pressure apparatus according to an embodiment of the present disclosure.

FIG. 5B is a schematic diagram showing an expanded view of a seal region of an internally-heated high-pressure apparatus according to an alternative embodiment of the present disclosure.

FIG. 5C is a schematic diagram showing an expanded view of a seal region of an internally-heated high-pressure apparatus according to another alternative embodiment of the present disclosure.

FIG. 5D is a schematic diagram showing another alternative internally-heated high-pressure apparatus according to an embodiment of the present disclosure.

FIG. 5E is a schematic diagram showing an expanded view of a seal region of an internally-heated high-pressure apparatus according to another alternative embodiment of the present disclosure.

FIGS. 5F1, 5F2 and 5F3 are schematic diagrams illustrating aspects of another alternative internally-heated high-pressure apparatus according to an embodiment of the present disclosure.

FIGS. 5G1, 5G2, 5G3 and 5G4 and 5H1, 5H2, 5H3, 5H4 and 5H5 are schematic diagrams showing various portions of a method for opening an internally-heated high-pressure apparatus, according to another alternative embodiment of the present disclosure.

FIGS. 6A and 6B are schematic diagrams showing expanded views of an upper portion of an internally-heated high-pressure apparatus according to an embodiment of the present disclosure.

FIG. 7 is a schematic diagram showing a radial temperature distribution within a radial cross section of an internally-heated high-pressure apparatus according to an embodiment of the present disclosure.

FIG. 8 is a schematic diagram showing is a simplified flow diagram of a method of processing a material within a supercritical fluid, according to an embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

According to the present disclosure, apparatus related to processing of materials for growth of crystals is provided. More particularly, the present disclosure provides an improved internally-heated high-pressure vessel for crystal growth of a material in a supercritical fluid, including crystal growth of a group III metal nitride crystal by an ammonobasic or ammonoacidic technique, but there can be others. In other embodiments, the present disclosure provides methods suitable for synthesis of crystalline nitride materials, but it would be recognized that other crystals and materials can also be processed. Such crystals and materials include, but are not limited to, GaN, AlN, InN, InGaN, AlGaN, and AlInGaN, and others for manufacture of bulk or patterned substrates. Such bulk or patterned substrates can be used for a variety of applications including optoelectronic devices, lasers, light emitting diodes, solar cells, photoelectrochemical water splitting and hydrogen generation, photodetectors, integrated circuits, and transistors, among other devices.

Approximating language, as used herein throughout the specification and claims, may be applied to modify any quantitative representation that could permissibly vary without resulting in a change in the basic function to which it may be related. Accordingly, a value modified by a term such as “about” may be not to be limited to the precise value specified. In at least one instance, the variance indicated by the term about may be determined with reference to the precision of the measuring instrumentation. Similarly, “free” may be combined with a term; and, may include an insubstantial number, or a trace amount, while still being considered free of the modified term unless explicitly stated otherwise.

The present disclosure focuses on improved internally-heated high-pressure apparatus for performing solvothermal crystal growth processes and processing materials in supercritical fluids. As noted above, solvothermal processes have a number of advantages for performing crystal growth in large volumes and are conventionally performed in externally-heated pressure vessels, which have limitations on maximum pressure and/or temperature, cost, and scalability. Internally-heated gas pressure vessels are well known in the art and are available in large volumes for maximum pressures in the range of approximately 50-200 megapascal (MPa). However, the use of a capsule for solvothermal crystal growth in such an apparatus may require independent control of both temperature and pressure, for example, as described by D'Evelyn, et al.

[U.S. Pat. No. 7,704,324], whereas with conventional pressure vessels it suffices to control only the temperature.

Extremely high pressures for solvothermal processing can be accessed using an internally-heated pressure vessel where a solid, deformable, pressure transmission medium separates a cylindrical heater from a high strength enclosure, for example, as described by D'Evelyn, et al. [U.S. Pat. Nos. 6,398,867 and 7,101,433]. However, this approach may imply single-use heaters and cell parts, relatively high costs, and limited scalability.

The use of a load-bearing, thermally-insulating, hard, sintered ceramic such as zirconia between a cylindrical heater and a high-strength enclosure can significantly reduce cost and improve apparatus scalability and lifetime for solvothermal process pressures in the range of approximately 25-2000 MPa and process temperatures in the range of 400-1200 degrees Celsius, for example, as described by D'Evelyn, et al. [U.S. Pat. No. 7,704,324] and by D'Evelyn [U.S. Pat. No. 8,097,081]. However, sintering requirements tend to limit the maximum value of a minimum dimension of ceramic parts, particularly a high-thermal-expansion composition such as zirconia, which can lead to a requirement for a large number of parts for large-volume apparatus. In addition, precision grinding of large ceramic parts can be undesirably costly.

It is an object of the present disclosure to provide an internally-heated high-pressure apparatus capable of performing solvothermal crystal growth at process pressures in the range of approximately 25-500 MPa, or 30-300 MPa, and process temperatures in the range of 200-900 degrees Celsius with improved scalability and reduced cost compared to previous designs. It is a further object of the present disclosure to provide methods for retrofitting a conventional externally-heated high-pressure vessel, such as an autoclave, into a compound internally-heated high-pressure apparatus suitable for ammonothermal crystal growth.

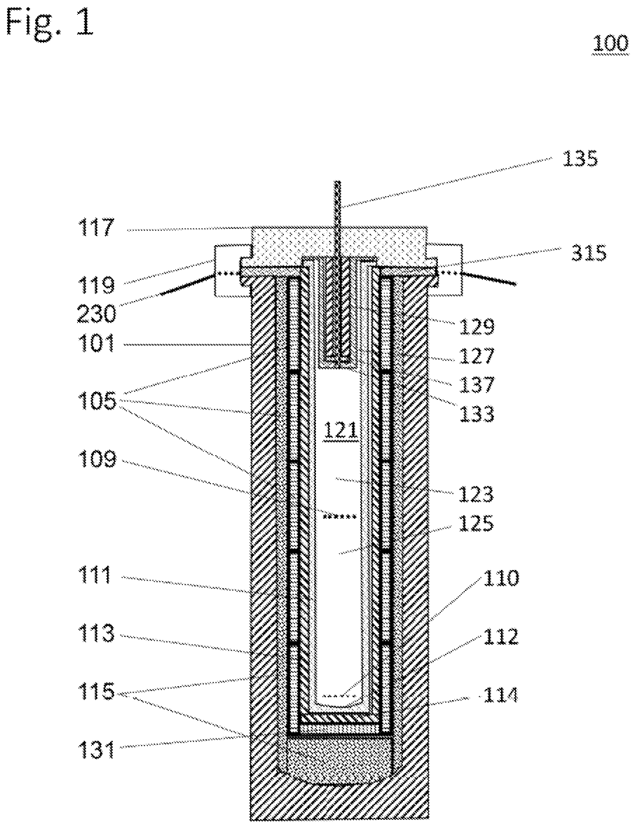

FIG. 1 is a simplified diagram of an internally-heated high-pressure apparatus according to an embodiment of the present invention. This diagram is merely an example, which should not unduly limit the scope of the claims herein. One of ordinary skill in the art would recognize other variations, modifications, and alternatives. As shown, the present invention provides an apparatus for high pressure crystal or material processing, e.g., GaN, AlN, InN, InGaN, AlGaN, and AlInGaN. Other processing methods include hydrothermal crystal growth of oxides and other crystalline materials, hydrothermal or ammonothermal syntheses, and hydrothermal decomposition, and others. Of course, there can be other variations, modifications, and alternatives.

Referring to FIG. 1, an internally-heated high-pressure apparatus and related methods for processing materials in supercritical fluids are disclosed. The internally-heated high-pressure apparatus may be capable of processing a material in a fluid at a pressure above about 5 MPa and below about 500 MPa, below about 400 MPa, below about 300 MPa, below about 200 MPa, or below about 100 MPa, at temperatures between about 50 degrees Celsius and about 900 degrees Celsius, between about 100 degrees Celsius and about 800 degrees Celsius, between about 150 degrees Celsius and about 700 degrees Celsius, or between about 200 degrees Celsius and about 600 degrees Celsius. Referring to FIG. 1, internally-heated high-pressure apparatus 100 includes an autoclave body, or high-strength enclosure 101, which is often referred to herein as a cylindrical enclosure or a cylindrical-shaped enclosure. In certain embodiments, a primary liner 111 is placed within a cavity of autoclave body 101. The primary liner can be used to isolate the processing region of the internally-heated high-pressure apparatus from the supporting elements that are positioned radially outward of the primary liner, including autoclave body 101. Primary liner 111 may be formed from or may include one or more of platinum, palladium, iridium, a Pt/Ir alloy, gold, silver, or an alloy thereof. In certain embodiments, the primary liner 111 is selected from a material that will not significantly generate corrosion products when exposed to the components used in the solvothermal crystal growth process. Primary liner 111 may also include or be formed from one or more of titanium, rhenium, copper, iron, nickel, cobalt, stainless steel, zirconium, tantalum, molybdenum, niobium, alloys thereof, or the like. Primary liner 111 may have a thickness between about 0.25 millimeter and about 200 millimeters, between about 0.5 millimeter and about 100 millimeters, between about 1 millimeter and about 50 millimeters, between about 2 millimeters and about 25 millimeters, or between about 3 millimeters and about 15 millimeters.

One or more baffles 109 may be positioned within primary liner 111, as is known in the art. Baffle 109 may include one or more disks, conical portions, spheroidal portions, or the like, with one or more perforations and annular gaps with respect to the inner diameter of primary liner 111, to allow for restricted fluid motion through the baffle. Baffle 109 may divide interior region 121 of primary liner 111 into upper zone 123 and lower zone 125. In certain embodiments, a bottom baffle 110 may be provided within a certain distance, for example, within 250 millimeters, within 100 millimeters, or within 50 millimeters, of the bottom inner surface 112 of primary liner 111. Baffle 109 and bottom baffle 110, if present, may be formed from or may include one or more of platinum, palladium, iridium, a Pt/Ir alloy, gold, silver, titanium, rhenium, copper, iron, nickel, cobalt, stainless steel, zirconium, tantalum, molybdenum, niobium, alloys thereof, or the like. Bottom baffle 112 may have the form of a flat disk. Bottom baffle 112 may include one or more holes, which may have a diameter between about 1 millimeter and about 25 millimeters. An annular gap may be present between the outer diameter of bottom baffle 112 and an inner diameter of primary liner 111 between about 0.5 millimeter and about 25 millimeters. In certain embodiments, the baffle 109 and baffle 112 are selected from a material that will not significantly generate corrosion products when exposed to the components used in the solvothermal crystal growth process.

In certain embodiments, all or portions of primary liner 111 are surrounded by secondary liner 113. Secondary liner 113 may provide mechanical support for primary liner 111, and may also serve to improve the temperature uniformity of surfaces of primary liner 111 during processes at elevated temperature. Secondary liner 113 may include or consist of one or more of steel, stainless steel, carbon steel, nickel, nickel-based alloy, Inconel®, Inconel® 625, Inconel® 718, Hastelloy®, René® 41, Waspalloy®, Mar-M 247®, Monel®, Stellite®, copper, copper-based alloy, zirconium, niobium, molybdenum, tantalum, tungsten, rhenium, platinum, platinum-based alloy, palladium, iridium, ruthenium, rhodium, osmium, titanium, vanadium, chromium, chromium-based alloy, iron, iron-based alloy, gold, silver, or aluminum, combinations of any of the foregoing, or the like. Secondary liner 113 may have a thickness between about 0.5 millimeter and about 200 millimeters, between about 1 millimeter and about 100 millimeters, between about 2 millimeters and about 50 millimeters, or between about 3 millimeters and about 25 millimeters. In certain embodiments, secondary liner 113 includes or consists of cylindrical members that are coaxially stacked upon each other. In certain embodiments, one or more stacked cylindrical members are tack-welded or welded to at least one adjacent stacked cylindrical member.

In certain embodiments, internally-heated high-pressure apparatus 100 further includes autoclave cap 117 and closure fixture 119, as shown schematically, plus a high-pressure seal (not shown in FIG. 1, but see below). The configuration shown in FIG. 1 is a schematic representation of a c-ring seal. In other embodiments, internally-heated high-pressure apparatus 100 includes one or more of a Grayloc™ seal, an unsupported Bridgman seal, an o-ring seal, a confined gasket seal, a bolted closure, an AE™ closure, an EZE-Seal™, a Keuntzel closure, a ZipperClave™ closure, a threadless pin closure, a Gasche™ gasket seal, or a weld seal. In certain embodiments, internally-heated high-pressure apparatus 100 further includes a cap, closure fixture, and seal on the lower end, in addition to the cap, closure fixture, and seal on the upper end.

Autoclave body 101, autoclave cap 117, and closure fixture 119 may each be fabricated from a material selected from a group consisting of steel, low-carbon steel, SA723 steel, SA266 carbon steel, 4340 steel, A-286 steel, iron based superalloy, nickel based superalloy, cobalt based superalloy, Inconel 718, Rene 41, 304 stainless steel, 310 stainless steel, 316 stainless steel, 340 stainless steel, 410 stainless steel, and 17-4 precipitation hardened stainless steel, zirconium and its alloys, titanium and its alloys, and other materials commonly known as Monel, Inconel, Hastelloy, Udimet 500, Stellite, Rene 41, and Rene 88. One or more of the components comprising autoclave body 101, autoclave cap 117, and closure fixture 119 may undergo a heat treatment operation. In certain embodiments, autoclave body 101 includes a seal at the bottom as well as at the top.

Load-bearing insulator 115 and heating elements 105 are positioned radially between autoclave body 101 and primary liner 111 or secondary liner 113, if the latter is present. In certain embodiments, load-bearing insulator 115 includes a packed-bed ceramic composition. In certain embodiments, the packed-bed ceramic composition includes or consists of a non-sintered ceramic composition. The non-sintered composition may include or consist of a green body formed from or more powder compositions. The powder compositions may include or consist of one or more of zirconia, magnesia-partially-stabilized zirconia, yttria-stabilized zirconia, hafnia, magnesia, yttria, calcia, ceria, silica, alumina, Gd₂Zr₂O₇, (Zr,Hf)₃Y₄O₁₂, tungsten niobate, a rare earth phosphate, a rare earth molybdate, or a compound or mineral that includes one or more of these compositions. In certain embodiments, one or more non-sintered ceramic compositions are placed within an enclosure or a can-shaped structure (not shown). The enclosure or can-shaped structure may include or consist of one or more of steel, stainless steel, carbon steel, nickel, nickel-based alloy, Inconel® nickel-chromium and iron ahoy, Hastelloy® nickel-molybdenum-chromium alloy, René 41® nickel-based alloy, Waspalloy® nickel-based ahoy, Mar-M 247® polycrystalline cast nickel-based ahoy, Monel® nickel-copper alloy, Stellite® cobalt-chromium alloy, copper, copper-based alloy, zirconium, niobium, molybdenum, tantalum, tungsten, rhenium, platinum, platinum-based alloy, palladium, iridium, ruthenium, rhodium, osmium, titanium, vanadium, chromium, iron, iron-based alloy, gold, silver, or aluminum, combinations thereof, and the like. One or more components of the enclosure or can may have a thickness between about 0.5 millimeter and about 50 millimeters, or between about 1 millimeter about 25 millimeters and may be formed by machining, water-jet cutting, electric-discharge machining, or the like, from plate, sheet, or foil stock.

In certain embodiments, a packed-bed ceramic composition within load-bearing insulator 115 includes or consists of a plurality of sintered primary components in an enclosure (not shown). In certain embodiments, the sintered primary components have a maximum dimension between about 1 millimeter and about 500 millimeters, between about 2 millimeters and about 100 millimeters, or between about 3 millimeters and about 50 millimeters. The sintered primary components may have a minimum dimension between about 10% and 100% of the maximum dimension. In some embodiments, load-bearing insulator 115 further includes a plurality of sintered secondary components within the enclosure. The sintered secondary components may have a maximum dimension between about 5% and about 30% of the maximum dimension of the sintered primary components. In certain embodiments, the sintered secondary components consist of pellets or granules, with a maximum dimension between about 1 millimeter and about 10 millimeters. In some embodiments, load-bearing insulator 115 further includes a plurality of sintered tertiary components. The sintered tertiary components may have a maximum dimension between about 5% and about 30% of the maximum dimension of the sintered secondary components. In certain embodiments, one or more of the sintered primary components, the sintered secondary components, and the sintered tertiary components may include or consist of a sintered ceramic composition. In certain embodiments, the sintered ceramic composition includes or consists of one or more of zirconia, magnesia-partially-stabilized zirconia, yttria-stabilized zirconia, hafnia, magnesia, yttria, calcia, ceria, silica, alumina, Gd₂Zr₂O₇, (Zr,Hf)₃Y₄O₁₂, tungsten niobate, a rare earth phosphate, a rare earth molybdate, or a compound or mineral that includes one or more of these compositions. In certain embodiments, one or more of the sintered primary components, the sintered secondary components, and the sintered tertiary components may include or consist of a natural rock or mineral composition. In certain embodiments, the natural rock or mineral composition includes or consists of a mafic igneous rock or mineral that is dominated by the silicates pyroxene, amphibole, olivine, and mica, such as basalt. In certain embodiments, the natural rock or mineral composition includes or consists of granite. In some embodiments, the natural rock or mineral is provided in the form of a river rock, which generally has a smooth and/or rounded shape. In a specific embodiment, the sintered primary components include or consist of river rocks, the sintered secondary components include or consist of river gravel or river pebbles, and the sintered tertiary components include or consist of sand.

In certain embodiments, load-bearing insulator 115 includes or consists essentially of a metallic composition. In certain embodiments, the metallic composition includes or consists of stacked or rolled metal foil, the foil having a thickness between about 0.03 millimeter and about 5 millimeters, between about 0.1 millimeters and about 2 millimeters, or between about 0.2 millimeters and about 1 millimeter. In certain embodiments, the metallic composition includes or consists of at least one of steel, stainless steel, carbon steel, nickel, nickel-based alloy, iron, iron-based alloy, titanium, vanadium, chromium, titanium-based alloy, Ti-6A 4V alloy, Inconel® nickel-chromium and iron alloy, Inconel®. 718, HasteHoy® nickel-molybdenum-chromium alloy, René 41® nickel-based alloy, Waspalloy® nickel-based alloy, Mar-M 247® polycrystalline cast nickel-based alloy. SteHite® cobalt-chromium alloy, zirconium, niobium, molybdenum, tantalum, tungsten, or rhenium. In certain embodiments, the metal foil includes perforations haying a diameter between about 1 millimeter and about 25 millimeters, between about 2 millimeters and about 20 millimeters, or between about 3 millimeters and about 15 millimeters. In certain embodiments, the areal fraction of the perforations within the metal foil is between about 5% and about 80%, between about 20% and about 70%, or between about 30% and about 60%.

In preferred embodiments, load-bearing insulator 115 has a thermal conductivity between about 0.1 and about 10 W/m-K, between about 0.2 and about 5 W/m-K, between about 0.25 and about 3 W/m-K, or between about 0.3 and about 2 W/m-K.

In certain embodiments, heating elements 105 include a cylindrical tube having grooves or channels machined into its outer surface. The cylindrical tube may include or consist of one or more of steel, stainless steel, an iron-based alloy, a nickel-based alloy or superalloy, Inconel 718™ Hastelloy X™, a cermet, ceramic, a glass ceramic, or a composite material. In certain embodiments, heating elements 115 include one or more of a cartridge heater, a tubular heater, a cable heater, a nickel-chromium wire, a Kanthal A-1™ wire, or a cylindrical ceramic insulating sleeve.

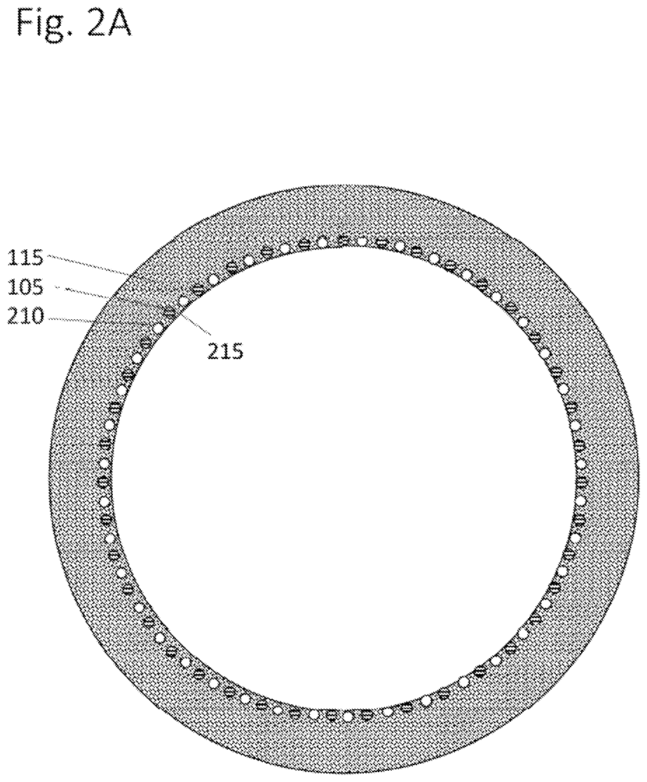

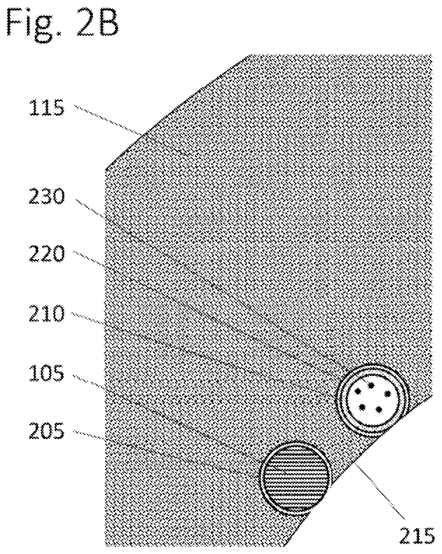

In certain preferred embodiments, heating elements 105 are embedded within load-bearing insulator 115. For example, referring to FIGS. 2A and 2B, heating elements 105 may be located radially proximate to the inner diameter 215 of load-bearing insulator 115. Heating elements 115 may be located within cylindrical heater enclosures 205, as shown schematically in FIG. 2B. In certain embodiments, cylindrical heater enclosures 205 are welded to inner diameter 215, which may form a portion of an enclosure for load-bearing insulator 115. In certain embodiments, heating elements 115 may include or consist of a cartridge heater, a tubular heater, a cable heater, a nickel-chromium wire, a Kanthal A-1™ wire, a cylindrical ceramic insulating sleeve. In certain embodiments, one or more thermocouples are embedded within heating elements 105. In certain embodiments, as shown schematically in FIG. 1, heating elements 105 have a length less than that of autoclave body 101, necessitating placement of two or more heating elements 105 one above another. Referring again to FIGS. 2A and 2B, in certain embodiments, lead conduits 210 are also placed radially proximate to inner diameter 215 of load-bearing insulator 115. Lead conduits 210 may include or consist of one or more of ceramic, glass, glass-ceramic, or metal tubes. In a specific embodiment, lead conduits 210 consist essentially of alumina tubes. In certain embodiments, lead conduits 210 are located within cylindrical conduit enclosures 220. In certain embodiments, cylindrical conduit enclosures 220 are welded to inner diameter 215, which may form a portion of an enclosure for load-bearing insulator 115. One or more electrical leads 230, thermocouple leads, or the like, from heating elements 105 or thermocouples from lower positions within autoclave body 101 may pass through lead conduits 210.

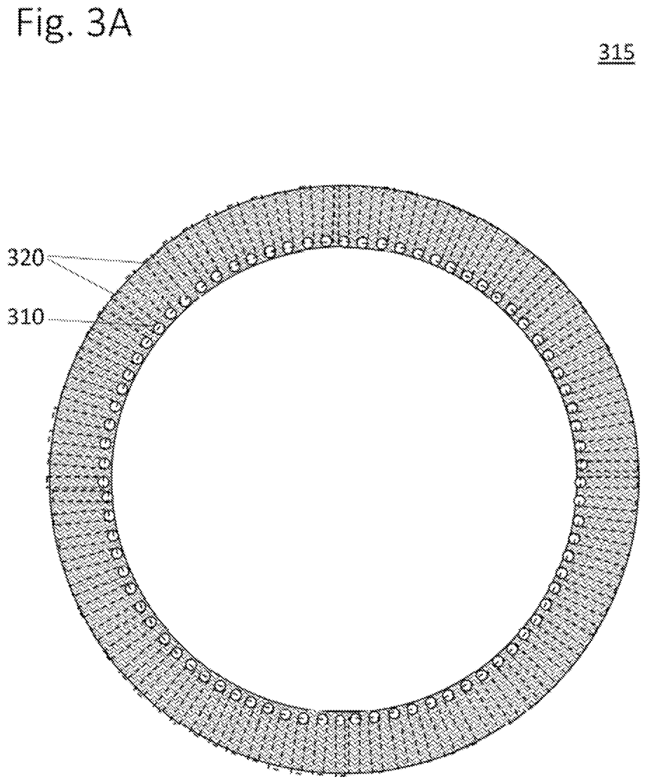

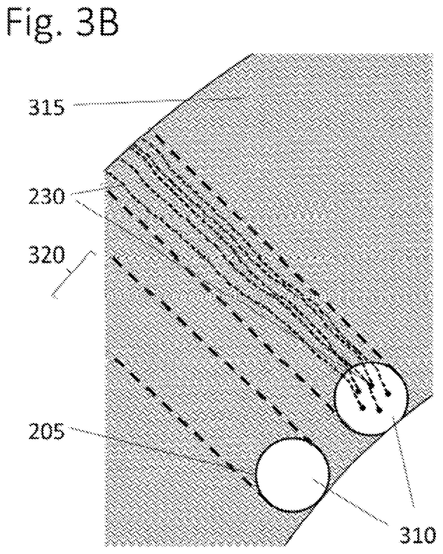

Referring again to FIGS. 1, 2A, and 2B, and also to FIGS. 3A and 3B, electrical leads 230 and thermocouple leads may be fed upward through lead conduits 210 to lead collar 315, where they may take a 90-degree bend and be fed outward to make external connections, for examples, to an electrical power control system and/or to a temperature monitoring station (not shown). Lead collar 315 may have vertically-oriented holes 310 and horizontally-oriented holes 320, through which electrical leads 230 and thermocouple leads may be threaded.

Referring again to FIG. 1, high-pressure apparatus 100 may further include a bottom end heater 131 that is thermally coupled to the bottom portion 112 of primary liner 111 and to bottom portion 114 of secondary liner 113, if the latter is present. The resistive heating elements within the bottom end heater 131 generate a power distribution that is approximately azimuthally uniform about the axis of autoclave body 101. The power level in bottom end heater 131, relative to the power levels in heating elements 115, along with the radial dependence of the power density within bottom end heater 131, is chosen so as to maintain a temperature distribution along bottom inner surface 112 or, alternatively, along bottom baffle 110, that is uniform to within 10 degrees Celsius, within 5 degrees Celsius, within 2 degrees Celsius, within 1 degree Celsius, within 0.5 degree Celsius, or within 0.2 degree Celsius. In certain embodiments, the power level in bottom end heater 131, relative to the power levels in heating elements 115, along with the radial dependence of the power density within bottom end heater 131, is chosen so as to maintain an average temperature of bottom inner surface 112 or, alternatively, of bottom baffle 110, that is equal to the average temperature of a lower portion of the inner surface of inner liner 111, within a specified height, measured with respect to bottom inner surface 112, to within 20 degrees Celsius, within 10 degrees Celsius, within 5 degrees Celsius, within 2 degrees Celsius, or within 1 degree Celsius. In certain embodiments the specified height is approximately 1 centimeter, 5 centimeters, 10 centimeters, 20 centimeters, or 25 centimeters. In certain embodiments, the bottom end heater 131 is configured with at least two or at least three independently-controllable hot zones.

Referring again to FIG. 1, upper zone 123 of interior region 121 is enclosed on the top by primary liner lid 127. Primary liner lid 127 may be formed from or may include one or more of platinum, palladium, iridium, a Pt/Ir alloy, gold, or silver. In certain embodiments, the primary liner lid 127 is selected from a material that will not significantly generate corrosion products when exposed to the components used in the solvothermal crystal growth process. Primary liner lid 127 may also include or be formed from one or more of titanium, rhenium, copper, iron, nickel, cobalt, stainless steel, zirconium, tantalum, molybdenum, niobium, alloys thereof, and the like. Primary liner lid 127 may have a thickness between about 0.25 millimeter and about 200 millimeters, between about 0.5 millimeter and about 100 millimeters, between about 1 millimeter and about 50 millimeters, or between about 2 millimeters and about 25 millimeters. In certain embodiments, primary liner lid 127 has a re-entrant structure, with a lower end that is positioned below the top of autoclave body 101 by at least 10 millimeters, at least 0.1 meter, by at least 0.2 meter, or by at least 0.5 meter. In certain embodiments, an annular radial gap between an outer diameter of a lower portion of primary liner lid 127 and an inner diameter of primary liner 111 is between about 0.1 millimeter and about 50 millimeters, between about 0.5 millimeter and about 25 millimeters, between about 1 millimeter and about 10 millimeters, or between about 2 millimeters and about 5 millimeters. In certain embodiments, annular support member 129 is placed within the re-entrant portion of primary liner lid 127, to provide radial and axial support for primary liner lid 127.

In certain embodiments, annular support member 129 includes or consists of one or more ceramic members. In certain embodiments, the ceramic members include or consist of one or more of alumina, silicon nitride, silicon carbide, zirconia, or the like. In certain embodiments, annular support member 129 includes a non-sintered ceramic composition placed within an enclosure or a can-shaped structure. In certain embodiments, annular support member 129 includes a plurality of sintered primary components in an enclosure. In certain embodiments, annular support member 129 is characterized by a thermal conductivity between 0.1 and 10 W/m-K, between 0.2 and 5 W/m-K, between 0.25 and 3 W/m-K, or between 0.3 and 2 W/m-K.

In certain embodiments, annular support member 129 provides axial support for bottom portion 133 of primary liner lid 127 through annular support disk 137. Annular support disk 137 may have a thickness between about 1 millimeter and about 100 millimeters, between about 2 millimeters and about 50 millimeters, or between about 5 millimeters and about 25 millimeters. Annular support disk 137 may include or consist of one or more of steel, stainless steel, carbon steel, nickel, nickel-based alloy, Inconel®, Inconel® 625, Inconel® 718, Hastelloy®, René® 41, Waspalloy®, Mar-M 247®, Monel®, Stellite®, copper, copper-based alloy, zirconium, niobium, molybdenum, tantalum, tungsten, rhenium, platinum, platinum-based alloy, palladium, iridium, ruthenium, rhodium, osmium, titanium, Ti-6A1-4V alloy, vanadium, chromium, chromium-based alloy, iron, iron-based alloy, gold, silver, or aluminum, combinations of any of the foregoing, and the like. In certain embodiments, annular support disk 137 may include or consist of one or more of Inconel® 718, Hastelloy®, Reno® 41, Waspalloy®, Mar-M 247®, or another nickel-based superalloy, an iron-based superalloy, or a cobalt-based superalloy.

In certain embodiments, annular support member 129 includes or consists of at least one perforated metal foil or a plurality of perforated metal plates that are wrapped tightly around one another in a radial direction within an inner diameter the autoclave body 101. Each of the at least one perforated metal foil or a plurality of perforated metal plates can include a series of holes, cutouts or material relieving feature on the contacting surfaces on the opposing sides of the perforated metal foil or perforated metal plates as they are wrapped in the radial direction. In certain embodiments, the at least one perforated metal foil or the perforated metal plates have an individual thickness between about 0.05 millimeter and about 20 millimeters, between about 0.1 millimeter and about 10 millimeters, or between about 0.2 millimeters and about 5 millimeters. In certain embodiments, the at least one perforated metal foil or the perforated metal plates include or consist of one or more of steel, stainless steel, carbon steel, nickel, nickel-based alloy, Inconel®, Inconel® 625, Inconel® 718, Hastelloy®, René® 41, Waspalloy®, Mar-M 247®, Monel®, Stellite®, copper, copper-based alloy, zirconium, niobium, molybdenum, tantalum, tungsten, rhenium, platinum, platinum-based alloy, palladium, iridium, ruthenium, rhodium, osmium, titanium, Ti-6Al-4V alloy, vanadium, chromium, chromium-based alloy, iron, iron-based alloy, gold, silver, or aluminum, combinations of any of the foregoing, and the like. In certain embodiments, the perforated foil or metal plates include or consist of may include or consist of one or more of Inconel® 718, Hastelloy®, René® 41, Waspalloy®, Mar-M 247®, or another nickel-based superalloy, an iron-based superalloy, or a cobalt-based superalloy. In certain embodiments, the perforations have a diameter between about 1 millimeter and about 25 millimeters, between about 2 millimeters and about 15 millimeters, or between about 3 millimeters and about 10 millimeters. The percent open area of the perforations within each foil or metal plate may be between about 25% and about 90%, between about 35% and about 80%, or between about 40% and about 65%. The foil or stack of perforated metal plates may have an average thermal conductivity in the axial direction between about 0.1 and about 10 W/m-K, between about 0.2 and about 5 W/m-K, or between about 0.25 and about 3 W/m-K.

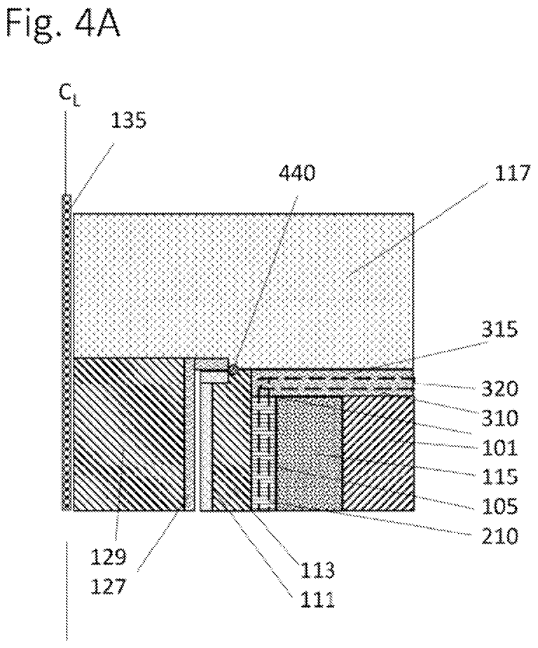

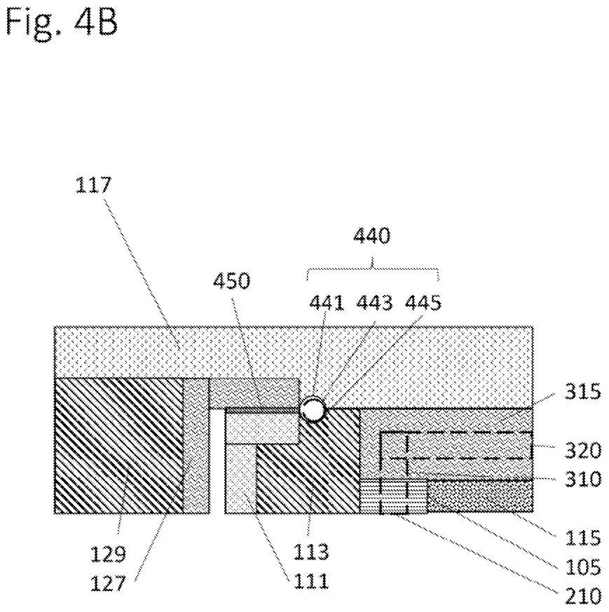

In certain embodiments, a demountable seal is provided for interior region 121 (FIG. 1) of internally-heated high-pressure apparatus 100. Referring to FIGS. 4A and 4B, in certain embodiments, a demountable seal 440 is provided between autoclave cap 117 and secondary liner 113, which surrounds the outside surface of the primary liner 111. In certain embodiments, as shown schematically in FIG. 4B, demountable seal 440 includes upper groove 441 in autoclave cap 117, lower groove 445 in secondary liner 113, and c-ring gasket 443, which is disposed within the upper groove 441 and the lower groove 445. In certain embodiments, primary liner 111 and primary liner lid 127 include or consist of materials that are soft and/or are subject to cold welding during operation at high temperature and pressure process conditions. For these latter embodiments, it may be preferred to place demountable seal 440 proximate to but outside primary liner 111 and primary liner lid 127, and to position liner gasket 450 between primary liner 111 and primary liner lid 127, as shown schematically in FIG. 4B. Liner gasket 450 may include or consist of a material that will not allow the primary liner 111 and primary liner lid 127 to cold weld under process conditions and, typically, will include or consist of a different material than that of primary liner 111 or primary liner lid 127. Liner gasket 450 may be formed from or may include one or more of platinum, palladium, iridium, a Pt/Ir alloy, gold, silver, titanium, rhenium, copper, iron, nickel, cobalt, stainless steel, zirconium, tantalum, molybdenum, niobium, alloys thereof, and the like. While a supercritical-fluid-tight seal may be provided by demountable seal 440 rather than by liner gasket 450, liner gasket 450 may minimize transport of potentially-corrosive reagents from interior region 121 to autoclave top 117, secondary liner 113, or other components of internally-heated high-pressure apparatus 100, and transport of corrosion products back into interior region 121. In certain embodiments, one or more of components of demountable seal 440, portions of autoclave cap 117, portions of secondary liner 113, or other components that are proximate to seal 440, are coated or plated to reduce the potential for corrosion. In certain embodiments, the coating or plating includes or consists of one or more of platinum, palladium, iridium, a Pt/Ir alloy, gold, silver, titanium, rhenium, copper, iron, nickel, cobalt, stainless steel, zirconium, tantalum, molybdenum, niobium, alloys thereof, and the like. In certain embodiments, the coating or plating is deposited by electroplating, electroless plating, plasma spraying, vacuum evaporation, or the like.

While the specific embodiment for demountable seal 440 shown in FIG. 4B is a c-ring seal, in other embodiments demountable seal 440 is configured to be a component of a Grayloc™ seal, an unsupported Bridgman seal, an o-ring seal, a confined gasket seal, a bolted closure, an AE™ closure, an EZE-Seal™, a Keuntzel closure, a ZipperClave™ closure, a threadless pin closure, or a Gasche™ gasket seal.

In certain embodiments, primary liner 111 and primary liner lid 127 are sufficiently hard to support a reliable, supercritical-fluid-tight seal and are not prone to cold welding, and demountable seal 440 is positioned between primary liner 111 and primary liner lid 127 rather than between autoclave cap 117 and secondary liner 113.

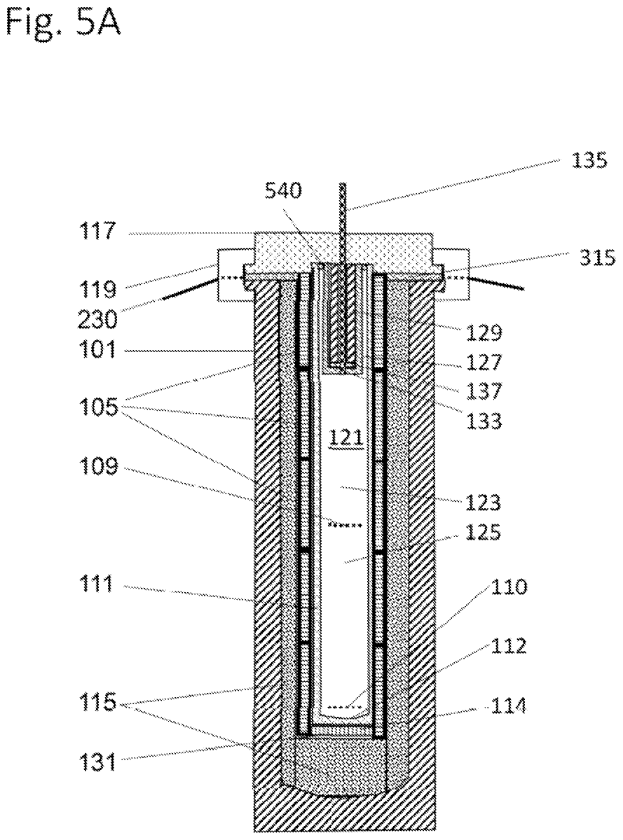

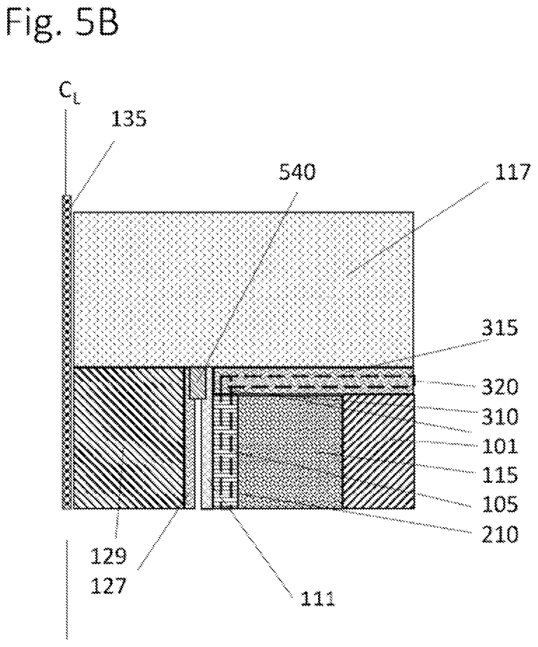

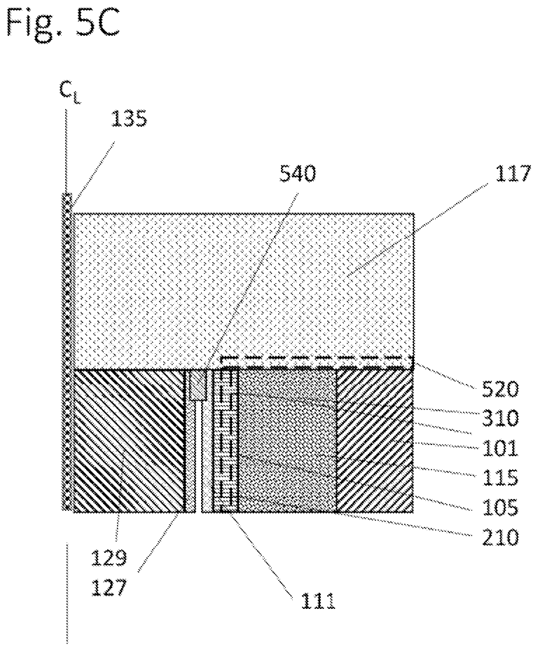

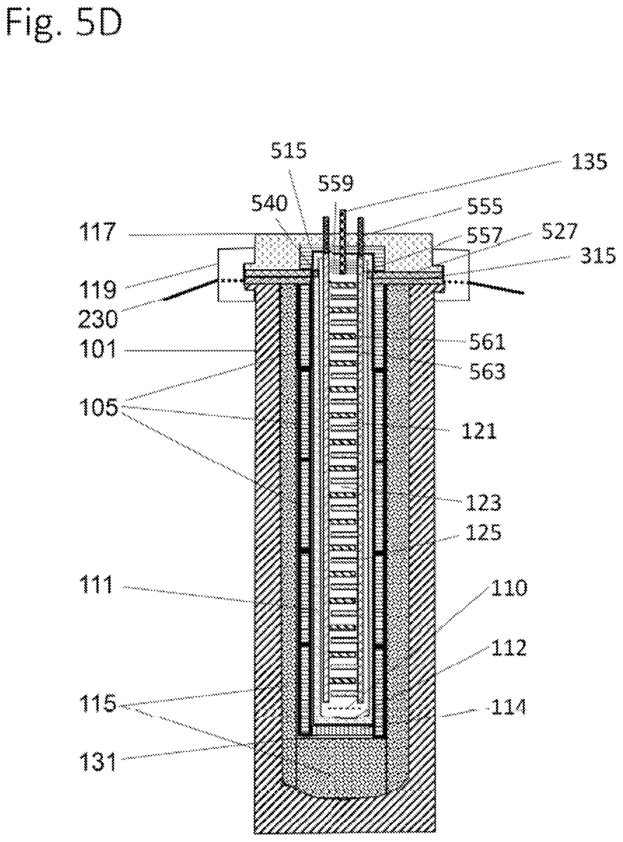

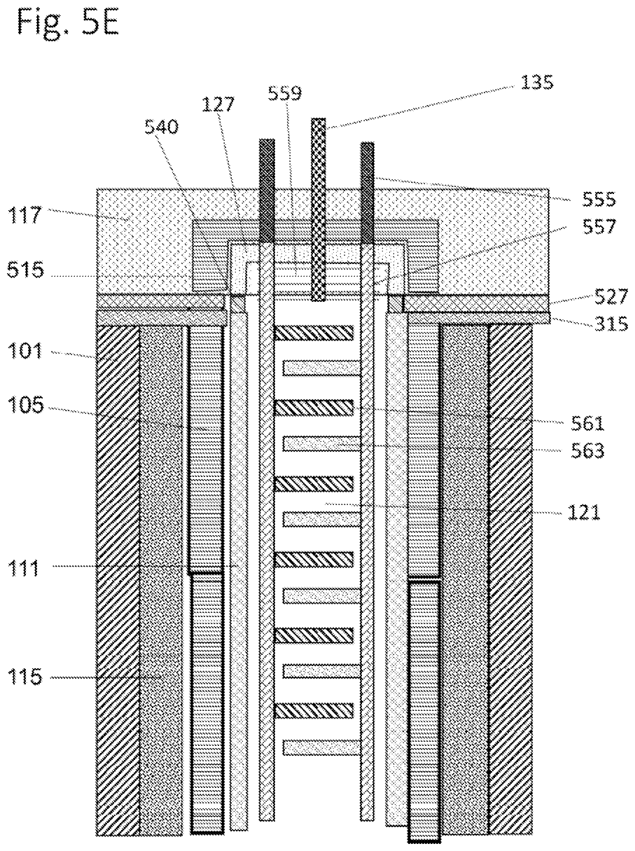

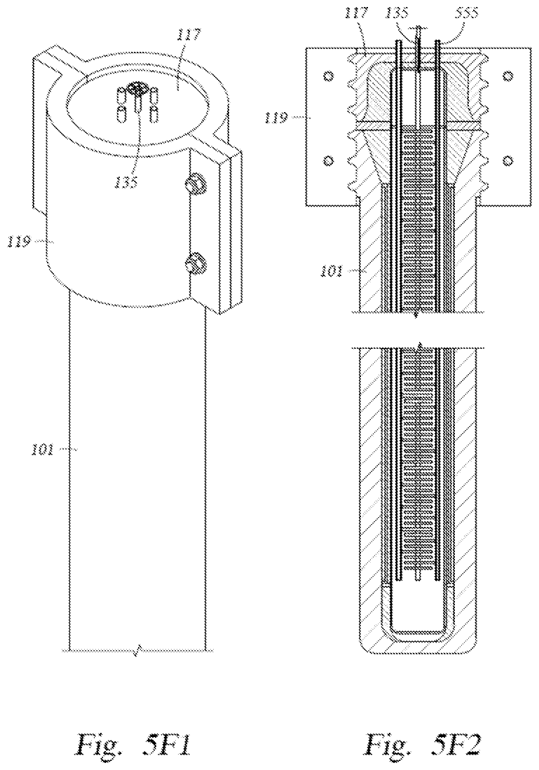

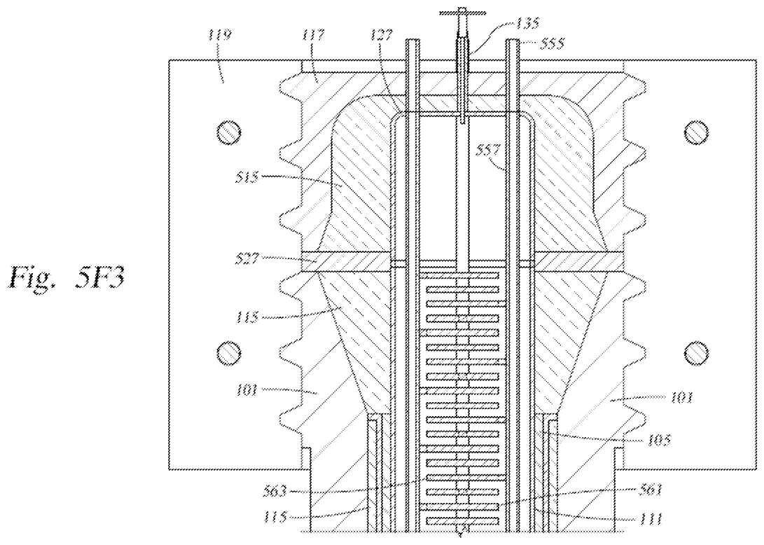

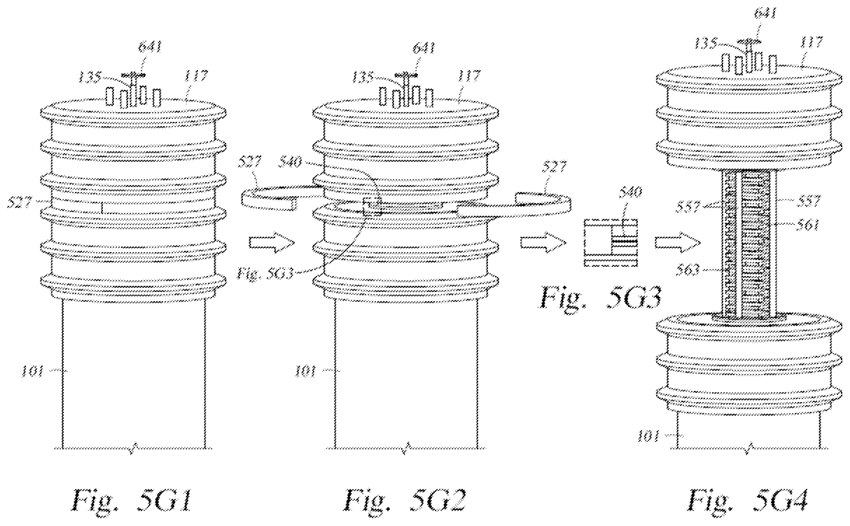

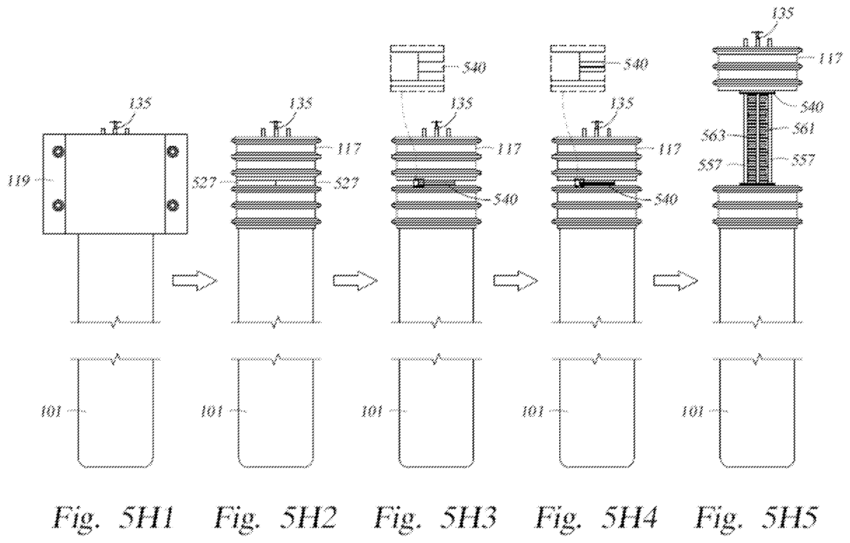

In certain embodiments, as shown schematically in FIGS. 5A, 5B, and 5C, a weld seal 540 is provided for interior region 121 of internally-heated high-pressure apparatus 100. In preferred embodiments, weld seal 540 has essentially the same composition as primary liner 111 and primary liner lid 127. Weld seal 540 may be formed by one or more of tungsten inert gas (TIG) welding, metal inert gas (MIG) welding, arc welding, orbital welding, torch welding, or the like. Weld seal 540 may include filler metal, a single-use component such as an annular ring, or the like. In certain embodiments, such as those shown schematically in FIGS. 5A, 5B, and 5C, secondary liner 113 is omitted from the internally-heated high-pressure apparatus. In certain embodiments, as shown schematically in FIG. 5C, lead collar 315 is omitted from the internally-heated high-pressure apparatus and electrical leads 230 and thermocouple leads may be fed upward through lead conduits 210 to a bottom portion of autoclave cap 117, where they may take a 90-degree bend and be fed outward through grooves 520 in autoclave cap 117 to make external connections, for examples, to an electrical power control system and/or to a temperature monitoring station (not shown).

In some embodiments, as shown schematically in FIGS. 5D, 5E, 5F, 5G and 5H, heating power is applied directly to one or more seed mounts 561 and nutrient supports 563, also referred to as temperature distribution units (TDUs). Heating elements may be placed within heater sheaths 557, which may be hermetically sealed to the primary liner lid 127, for example, by welding, brazing, swaging, or the like. In certain embodiments the heating elements include one or more of cartridge heaters or cable heaters. In certain embodiments, electrical leads pass through via tubes 555, emerging from heater sheaths 557, passing through load-bearing lid insulator 515 and end closure 117, and are connected to a power control system (not shown). In certain embodiments, one more of seed mounts 561 and nutrient supports 563 are attached to heater sheaths 557 by a thermally-conductive connection, for example, a weld or a clamp. In some embodiments, heating elements are embedded within one more of seed mounts 561 and nutrient supports 563 to directly control the temperature of these components during processing. In certain embodiments, one more of seed mounts 561 and nutrient supports 563 include or consist of a thermally conductive material, such as silver or molybdenum, to maintain a uniform temperature along the surfaces of the seed mounts 561 and nutrient supports 563. In certain embodiments, one more of seed mounts 561 and nutrient supports 563 are hollow and are filled with supercritical ammonia under process conditions. In certain embodiments, the temperatures of one more of seed mounts 561 and nutrient supports 563 may be controlled independently, allowing for precise control of the temperature difference between individual seed mounts 561 and nutrient supports 563. The precise control of the temperature difference between individual seed mounts 561 and nutrient supports 563 can be used to control convection loops generated in the supercritical fluid, which are formed between each of the seed mount 561 and nutrient support 563 pairs, during solvothermal crystal growth processes. The convection loops formed between the seed mount 561 and the nutrient support 563 pairs will allow the growth of seed crystals disposed on the surface of the seed mount 561.

In certain embodiments, primary liner lid 127 is positioned entirely above primary liner 111, as shown schematically in FIGS. 5D, 5E, 5F2, and 5F3, rather than being re-entrant, as in FIGS. 1, 4A, 4B, 5A, 5B, and 5C. Thermal insulation may be provided between primary liner lid 127 and end closure 117 by load-bearing lid insulator 515. FIG. 5F1 is a top partial isometric view of the internally-heated high-pressure apparatus 100, which illustrates the closure fixture 119 portion of the assembly. FIGS. 5F2 and 5F3 are cross-sectional views of portions of the internally-heated high-pressure apparatus 100. The materials of construction for load-bearing lid insulator 515 may be similar to those of load-bearing insulator 115. Additional thermal insulation between interior region 121 may be provided by top baffles 559 (FIGS. 5D and 5E). In certain embodiments, top baffles 559 include or consist essentially of solid disks, with an annular radial gap with respect to an inner diameter of primary liner lid 127 that is less than about 10 millimeters, less than about 5 millimeters, less than about 2 millimeters, or less than about 1 millimeter. The materials of construction of top baffles 559 may be similar to those of bottom baffle 110. In certain embodiments, access to weld seal 540 (FIGS. 5G2-5G4 and 5H3), which is also known as a hermetic makeup ring, that is formed between primary liner 111 and primary liner lid 127 is provided through split access collar 527.

FIGS. 5G1-5G4 and FIGS. 5H1-H5 each illustrate a progression of steps performed after performing a process run. For example, after a process run is completed, the closure fixture 119 (FIG. 5H1) may be removed, as shown in FIG. 5H2. Then, the split access collar 527 (FIG. 5H2) is removed, as shown in FIG. 5H3. Next, the weld seal 540 (FIG. 5H3) may be cut by sawing, machining, or the like to separate the primary liner lid 127 from primary liner 111, as shown in FIG. 5H4. The seed mounts 561, nutrient supports 563, and heater sheaths 557 and materials deposited on the seed crystals disposed on the seed mounts 561 can be removed from the interior region 121, as shown in FIG. 5H5.

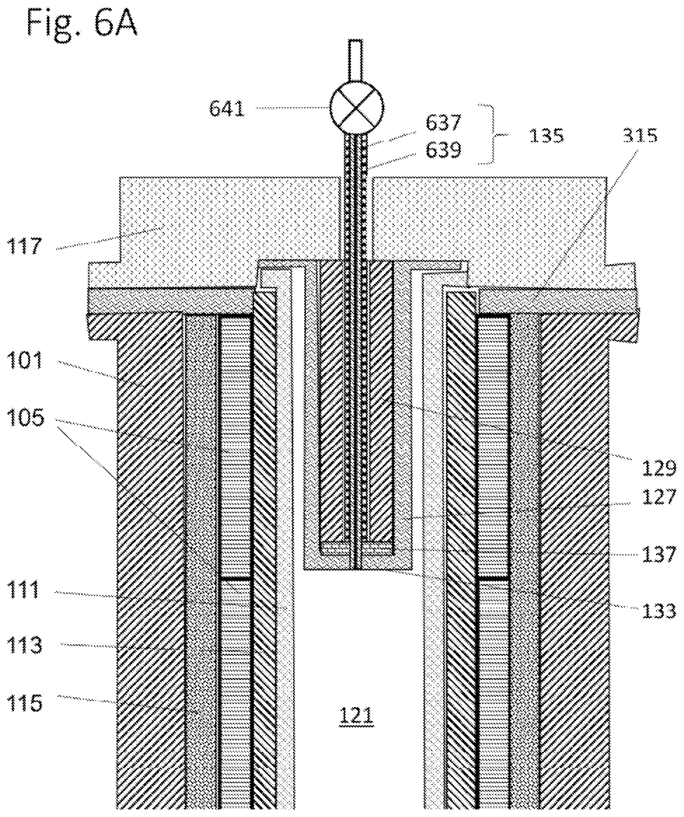

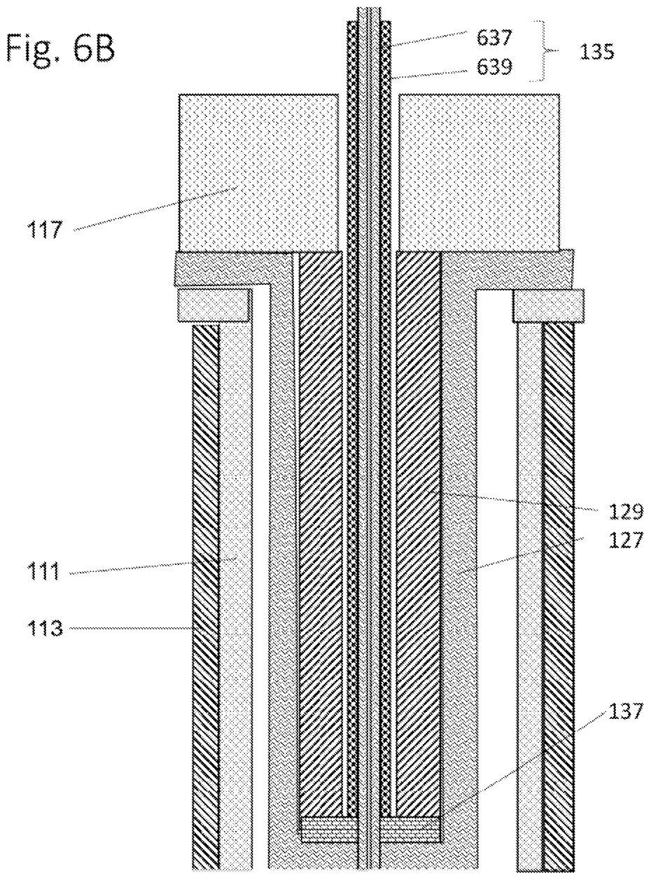

In certain embodiments, supported fill tube 135 is positioned within annular support member 129, through a hole in autoclave cap 117, as shown schematically in FIGS. 1, 4A, 5A, 5B, 5C, 5F2, 5F3, and 5G. Referring to FIGS. 6A and 6B, in certain embodiments supported fill tube 135 includes or consists of an inner fill tube 637, which is slidingly inserted in fill tube support tube 639. In certain embodiments, inner fill tube 637 may be formed from or may include one or more of platinum, palladium, iridium, a Pt/Ir alloy, gold, or silver. Inner fill tube 637 may also include or be formed from one or more of titanium, rhenium, copper, iron, nickel, cobalt, stainless steel, zirconium, tantalum, molybdenum, niobium, alloys thereof, or the like. Inner fill tube 637 may have a wall thickness between about 0.1 millimeter and about 50 millimeters, between about 0.25 millimeter and about 25 millimeters, between about 0.5 millimeter and about 10 millimeters, or between about 1 millimeter and about 5 millimeters. Inner fill tube 637 may have an inner diameter between about 0.5 millimeter and about 50 millimeters, between about 1 millimeter and about 25 millimeters, or between about 2 millimeters and about 15 millimeters. In certain embodiments, inner fill tube 637 has essentially the same composition as primary liner lid 127. In certain embodiments, a lower portion of inner fill tube 637 is welded to a lower portion 133 of primary liner lid 127. In certain embodiments, fill tube support tube 639 includes or consists of one or more of steel, stainless steel, carbon steel, nickel, nickel-based alloy, Inconel®, Inconel® 625, Inconel® 718, Hastelloy®, René® 41, Waspalloy®, Mar-M 247®, Monel®, Stellite®, copper, copper-based alloy, zirconium, niobium, molybdenum, tantalum, tungsten, rhenium, platinum, platinum-based alloy, palladium, iridium, ruthenium, rhodium, osmium, titanium, Ti-6A1-4V alloy, vanadium, chromium, chromium-based alloy, iron, iron-based alloy, gold, silver, or aluminum, combinations of any of the foregoing, and the like. In certain embodiments, fill tube support tube 639 includes or consists of one or more of Inconel® 718, Hastelloy®, René® 41, Waspalloy®, Mar-M 247®, or another nickel-based superalloy, an iron-based superalloy, or a cobalt-based superalloy. Fill tube support tube 639 may have a wall thickness between about 1 millimeter and about 100 millimeters, between about 2 millimeters and about 75 millimeters, between about 3 millimeters and about 50 millimeters, or between about 5 millimeters and about 30 millimeters. The diametric clearance between the inner diameter of fill tube support tube 639 and the outer diameter of inner fill tube 637 may be between about 0.05 millimeter and about 5 millimeters, between about 0.075 millimeter and about 2 millimeters, or between about 0.1 millimeter and about 1 millimeter.

Referring to FIG. 6A, an upper end of supported fill tube 135 may be attached to fill valve 641. In certain embodiments, fill valve 641 makes a gas-tight seal to inner fill tube 637 and has a rigid mechanical connection to fill tube support tube 637, thereby being capable of supporting a pressure from interior region 121 as transmitted through the inner diameter of inner fill tube 637.

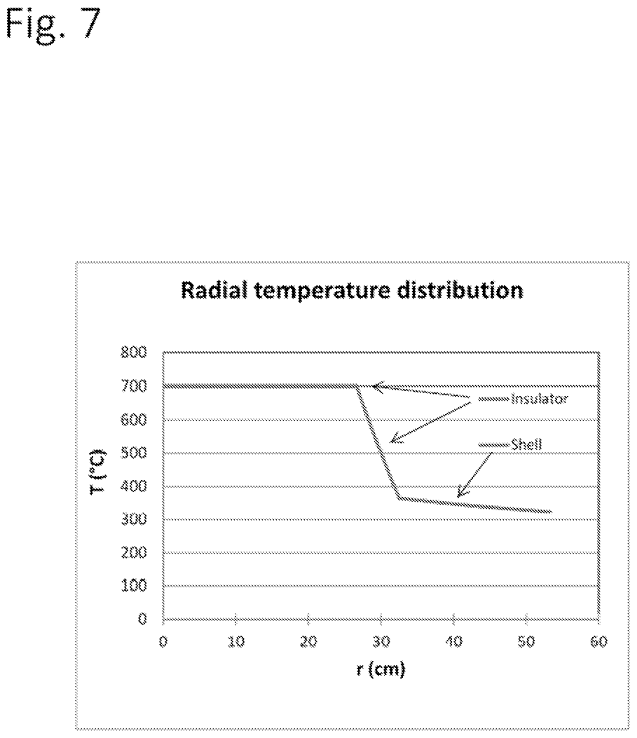

Referring again to FIGS. 1 and 5A-5H, in certain embodiments the outer diameter of autoclave body 101 is cooled by forced convection of a coolant, for example, a liquid coolant, in thermal contact with autoclave body 101. In preferred embodiments, however, the thickness of load-bearing insulator 115 is selected so that, for a given target temperature for a process within internally-heated high-pressure apparatus 100, the temperature of autoclave body 101 remains within the specified ratings even with external air cooling. For example, FIG. 7 shows the internal temperature distribution for the hot zone of an internally-heated high-pressure apparatus with an inner diameter of the load-bearing insulator 115 of 0.53 meters, an inner diameter of the autoclave body of 0.65 meters, and an outer diameter of the autoclave body of 1.07 meters, with an internal process temperature of 700 degrees Celsius, and cooling of the outer diameter of the autoclave body being provided by room-temperature air with a heat-transfer coefficient of 20 W/m²-K. The power required to run the process is reduced by more than 40 percent compared to the case where the outer diameter of autoclave body 101 is liquid-cooled, not counting the power required to cool the liquid.

Nitride single crystals, for example, gallium nitride, may be grown in internally-heated high-pressure apparatus 100 by the following procedure.

Seed crystals, for example, high-quality single crystal gallium nitride, may be attached to furniture by means of wires, clips, or the like. In some embodiments, the seed mounts 561 are utilized as part of the furniture that is inserted in to the interior region 121 during processing. The furniture may include or consist of one or more of copper, copper-based alloy, gold, gold-based alloy, silver, silver-based alloy, palladium, platinum, iridium, ruthenium, rhodium, osmium, titanium, vanadium, chromium, iron, iron-based alloy, nickel, nickel-based alloy, zirconium, niobium, molybdenum, tantalum, tungsten, rhenium, silica, alumina, combinations thereof, and the like, and may include one or more of wire, wire cloth or mesh, foil, plate, sheet, square bar, round bar, rectangular bar, tubing, threaded rod, and fasteners. Polycrystalline nutrient, for example, polycrystalline gallium nitride, may be added to a basket within the furniture. The furniture, including one or more baffles, may be placed within primary liner 111 of internally-heated high-pressure apparatus 100.

A solid mineralizer, for example, one or more of an alkali metal such as Li, Na, K, Rb, or Cs, an alkaline earth metal, such as Be, Mg, Ca, Sr, or Ba, or an alkali or alkaline earth hydride, amide, imide, amido-imide, nitride, or azide, an ammonium halide, such as NH₄F, NH₄Cl, NH₄Br, or NH₄, a metal halide, or a compound that may be formed by reaction of one or more of F, Cl, Br, I, HF, HCl, HBr, Hl, Al, AlN, and NH₃ with a metal, may be added to internally-heated high-pressure apparatus 100.

Internally-heated high-pressure apparatus 100 may then be closed, by placement of autoclave cap 117 over autoclave body 101 and actuation of demountable seal 440 via closure fixture 119. In certain embodiments, high-pressure apparatus is instead sealed by formation of weld seal 540. Internally-heated high-pressure apparatus 100 may then be evacuated through supported fill tube 135. The integrity of demountable seal 440 or weld seal 540 may be evaluated by helium leak-checking while internally-heated high-pressure apparatus 100 is under vacuum. The integrity of demountable seal 440 or weld seal 540 may be further tested by pressurizing internally-heated high-pressure apparatus 100 using a mixture of helium and nitrogen or argon to a pressure above 1 MPa, above 3 MPa, above 10 MPa, above 30 MPa, above 100 MPa, above 300 MPa, or above 1000 MPa and helium leak-checking on the outside of internally-heated high-pressure apparatus 100.

Residual air, moisture, and other volatile contaminants may be removed by evacuating internally-heated high-pressure apparatus 100 and heating, using heating elements 105, to a temperature between about 25 degrees Celsius and about 900 degrees Celsius, or between about 100 degrees Celsius and about 500 degrees Celsius, for a time between about 1 hour and about 1000 hours or between about 24 hours and about 250 hours. A plurality of pump/purge cycles may be employed.

In certain embodiments, a gas- or liquid-phase mineralizer may be added to the internally-heated high-pressure apparatus according to methods that are known in the art. In one specific embodiment, the mineralizer is HF, which may be added as a vapor or as a liquid. In certain embodiments, a solvent is added to the internally-heated high-pressure apparatus according to methods that are known in the art. In one specific embodiment, the solvent is ammonia, which is added at an elevated pressure.

The internally-heated high-pressure apparatus is then heated to a temperature above about 400 degrees Celsius and pressurized above about 50 megapascal to perform ammonothermal crystal growth.

A method of use according to a specific embodiment is briefly outlined below. Provide an apparatus for high-pressure crystal growth or material processing, such as the ones described above, but there can be others, the apparatus comprising an interior region (for example, cylindrical in shape) surrounded by radial and axial restraint structures, an opening region to the interior region being closable by a lid structure with a seal. Next, provide one or more raw materials into the interior region and close and seal the lid structure. and provide a solvent to the interior region. Then, provide the apparatus with thermal energy to cause an increase in temperature within the interior region to greater than 200 degrees Celsius to cause the solvent to be superheated. The process of superheating the solvent allows a crystalline material to form. The thermal energy is then removed from the apparatus to cause a temperature of the capsule to change from a first temperature to a second temperature, which is lower than the first temperature. The solvent is then released from the interior region, and then the interior region of the high-pressure apparatus is opened by opening the lid structure. The crystalline material can then be removed from the interior region. One or more additional steps may be performed as desired.

The above sequence of steps provides a method according to an embodiment of the present disclosure. In a specific embodiment, the present disclosure provides a method and resulting crystalline material provided by a compound, internally-heated high-pressure apparatus. Other alternatives can also be provided where steps are added, one or more steps are removed, or one or more steps are provided in a different sequence without departing from the scope of the claims herein. Details of the present method and structure can be found throughout the present specification and more particularly below.

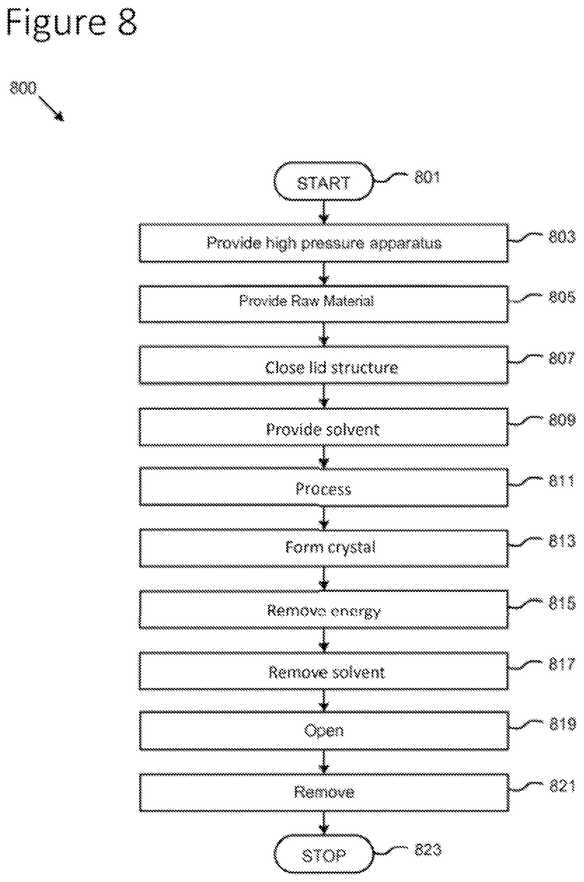

FIG. 8 is a simplified flow diagram 800 of a method of processing a material within a supercritical fluid. This diagram is merely an example, which should not unduly limit the scope of the claims herein.

In a specific embodiment, the method begins with start, step 801. The method begins by providing an apparatus for high-pressure crystal or material processing (see step 803), such as the one described above, but there can be others. In certain embodiments, the apparatus has an interior region (for example, cylindrical in shape) surrounded by radial and axial restraint structures. In certain embodiments, the opening region to the interior region are closable by lid closure structures.

In a specific embodiment, the method provides at least one raw material to the interior region (see step 805), followed by closing a lid structure that includes a seal (see step 807) and providing a solvent, such as ammonia into the interior region (see step 809), for example. In a specific embodiment, the raw materials include seed crystals and polycrystalline nutrient material. The method heats the interior region (see step 811) with thermal energy to cause an increase in temperature within the interior region to greater than 200 degrees Celsius to cause the solvent to be superheated and process the at least one raw material in the interior region.

Referring again to FIG. 8, the method forms a crystalline material (see step 813) from a process of the superheated solvent. In certain embodiments, the crystalline material comprises a gallium-containing nitride crystal such as GaN, AlGaN, InGaN, and others. In a specific embodiment, the method removes thermal energy from the capsule (see step 815) to cause a temperature within the interior region to change from a first temperature to a second temperature, which is lower than the first temperature. Once the energy has been removed and temperature reduced to a suitable level, the method removes a solvent from the interior region (step 817).

In a specific embodiment, the capsule is now free from the apparatus. In a specific embodiment, the interior region is opened, step 819. In cases where step 807 includes formation of weld seal 540, step 819 may include one or more of cutting, drilling, machining, griding, or the like of weld seal 540. In a specific embodiment, the crystalline material is removed from the interior region, step 821. Depending upon the embodiment, there can also be other steps, which can be inserted or added, or certain steps can also be removed. In a specific embodiment, the method ends at stop, step 823.

The above sequence of steps provides a method according to an embodiment of the present disclosure. In a specific embodiment, the present disclosure provides a method and resulting crystalline material provided by a compound internally-heated high-pressure apparatus. Other alternatives can also be provided where steps are added, one or more steps are removed, or one or more steps are provided in a different sequence without departing from the scope of the claims herein.

In certain embodiments, a gallium-containing nitride crystal or boule grown by methods such as those described above is sliced or sectioned to form wafers. The slicing, sectioning, or sawing may be performed by methods that are known in the art, such as internal diameter sawing, outer diameter sawing, fixed abrasive multiwire sawing, fixed abrasive multiblade sawing, multiblade slurry sawing, multiwire slurry sawing, ion implantation and layer separation, or the like. The wafers may be lapped, polished, and chemical-mechanically polished according to methods that are known in the art.

One or more active layers may be deposited on the well-crystallized gallium-containing nitride wafer. The active layer may be incorporated into an optoelectronic or electronic devices such as at least one of a light emitting diode, a laser diode, a photodetector, a photodiode, an avalanche photodiode, a transistor, a rectifier, and a thyristor; one of a transistor, a rectifier, a Schottky rectifier, a thyristor, a p-i-n diode, a metal-semiconductor-metal diode, high-electron mobility transistor, a metal semiconductor field effect transistor, a metal oxide field effect transistor, a power metal oxide semiconductor field effect transistor, a power metal insulator semiconductor field effect transistor, a bipolar junction transistor, a metal insulator field effect transistor, a heterojunction bipolar transistor, a power insulated gate bipolar transistor, a power vertical junction field effect transistor, a cascode switch, an inner sub-band emitter, a quantum well infrared photodetector, a quantum dot infrared photodetector, a solar cell, and a diode for photoelectrochemical water splitting and hydrogen generation.

While the foregoing is directed to embodiments of the present disclosure, other and further embodiments of the disclosure may be devised without departing from the basic scope thereof, and the scope thereof is determined by the claims that follow.

What is claimed is:

1. A crystal growth apparatus, comprising:
a cylindrical-shaped enclosure;
a primary liner disposed within the cylindrical-shaped enclosure, wherein the primary liner comprises a cylindrical wall that extends between a first end and a second end, and an interior surface of the primary liner defines an interior region;
at least one load-bearing annular insulating member disposed between the cylindrical-shaped enclosure and the primary liner;
a plurality of heating elements disposed between the primary liner and the at least one load-bearing annular insulating member;
at least one end closure member disposed proximate to a first end of the cylindrical-shaped enclosure;
a primary liner lid disposed proximate to the first end of the cylindrical wall of the primary liner; wherein:
the at least one load-bearing annular insulating member comprising at least one of:
a packed-bed ceramic composition, the packed-bed ceramic composition having a density that is between about 30% and about 98% of a theoretical density of a 100%-dense ceramic having the same composition; or
a perforated metal member, comprising a perforated metal foil or a plurality of perforated metal plates, wherein the perforations have a percent open area between about 25% and about 90%, and the perforations have a diameter between about 1 millimeter and about 25 millimeters.

2. The apparatus of claim 1, wherein the at least one load-bearing annular insulating member comprises a non-sintered ceramic composition contained within an enclosure that has a height between about 150 millimeters and about 50 meters and a diameter between about 25 millimeters and about 5 meters.

3. The apparatus of claim 1, wherein the packed-bed ceramic composition comprises a powder, and has a density that is between about 45% and about 70% of a theoretical density of a 100%-dense ceramic having the same composition and by a thermal conductivity between about 0.25 and about 3 watts per meter-Kelvin.

4. The apparatus of claim 1, wherein the at least one load-bearing annular insulating member comprises a plurality of sintered primary components disposed within an enclosure, wherein each of the plurality of sintered primary components have a maximum dimension between about 1 millimeter and about 500 millimeters.

5. The apparatus of claim 4, further comprising a plurality of sintered secondary components within the enclosure, wherein each of the plurality of sintered secondary components have a maximum dimension between about 5% and about 30% of the maximum dimension of the sintered primary components.

6. The apparatus of claim 5, further comprising a plurality of sintered tertiary components, wherein each of the sintered tertiary components have a maximum dimension between about 5% and about 30% of the maximum dimension of the sintered secondary components.

7. The apparatus of claim 4, wherein each of the plurality of sintered primary components comprises one or more of zirconia, magnesia-partially-stabilized zirconia, yttria-stabilized zirconia, hafnia, magnesia, yttria, calcia, ceria, silica, alumina, Gd₂Zr₂O₇, (Zr,Hf)₃Y₄O₁₂, tungsten niobate, a rare earth phosphate, a rare earth molybdate, or a compound or mineral that includes one or more of these compositions.

8. The apparatus of claim 4, wherein each of the plurality of sintered primary components comprises a natural rock or mineral composition.

9. The apparatus of claim 1, wherein the cylindrical-shaped enclosure comprises one or more of steel, low-carbon steel, SA723 steel, SA266 carbon steel, 4340 steel, A-286 steel, 304 stainless steel, 310 stainless steel, 316 stainless steel, 340 stainless steel, 410 stainless steel, or 17-4 precipitation hardened stainless steel.

10. The apparatus of claim 1, wherein the primary liner comprises one or more of platinum, palladium, iridium, a Pt/Ir alloy, gold, or silver, or an alloy or combination thereof.

11. The apparatus of claim 10, further comprising a secondary liner disposed between an outer diameter of the primary liner and an inner diameter of the at least one load-bearing annular insulating member, wherein the secondary liner comprises one or more of steel, stainless steel, an iron-based alloy, or a nickel-based alloy or superalloy.

12. The apparatus of claim 1, wherein the plurality of heating elements comprise at least one of a cartridge heater, a tubular heater, or a cable heater.

13. The apparatus of claim 1, wherein the plurality of heating elements are embedded within at least one of the at least one load-bearing annular insulating members.

14. The apparatus of claim 13, wherein at least one lead conduit is embedded within at least one of the at least one load-bearing annular insulating members.

15. The apparatus of claim 14, further comprising a lead collar, wherein the lead collar is disposed proximate to and between an upper surface of the cylindrical-shaped enclosure and a lower surface of at least one of the at least one end closure members and is configured to route electrical leads from at least one of the at least one lead conduits to an outer diameter of the apparatus.

16. The apparatus of claim 1, further comprising a secondary liner, the secondary liner being disposed between an outer diameter of the primary liner and an inner diameter of the at least one load-bearing annular insulating member.

17. The apparatus of claim 16, further comprising an end heater, the end heater being disposed proximate to a bottom portion of the secondary liner.

18. The apparatus of claim 1, wherein the primary liner lid has a re-entrant portion characterized by a lower end positioned by at least 0.1 meter below an upper surface of the cylindrical enclosure and is characterized by an annular radial gap between an outer diameter of the primary liner lid and an inner diameter of the primary liner by between 0.5 millimeter and 25 millimeters.

19. The apparatus of claim 18, further comprising an annular support member within the re-entrant portion configured to provide radial and axial support for the primary liner lid at a pressure above about 5 megapascal and less than about 500 megapascal and a temperature above about 200 degrees Celsius and less than about 900 degrees Celsius.

20. The apparatus of claim 1, wherein the plurality of heating elements is disposed proximate to an inner diameter of the at least one load-bearing annular insulating member.

21. The apparatus of claim 1, wherein the plurality of heating elements is disposed within the primary liner.

22. The apparatus of claim 16, wherein a seal is provided between the secondary liner and at least one of the at least one end closure member.

23. The apparatus of claim 1, wherein a seal is provided between the primary liner and the primary liner lid.

24. The apparatus of claim 1, wherein the at least one perforated metal foil or plurality of perforated metal plates is characterized by an individual thickness between about 0.1 millimeter and about 10 millimeters, a percent open area of perforations within each foil or metal plate between about 35% and about 80%, and comprise one or more of Inconel® 718, Hastelloy®, René® 41, Waspalloy®, Mar-M 247®, or another nickel-based superalloy, an iron-based superalloy, or a cobalt-based superalloy.
